(19) United States
(12) Patent Application Publication
(10) Pub. No.: US 2013/0334545 A1
(43) Pub. Date: Dec. 19, 2013

(54) Surface light source and display device

(71) Applicants: Che-chang Hu, Shenzhen (CN); Jie Ren, Shenzhen (CN)

(72) Inventors: Che-chang Hu, Shenzhen (CN); Jie Ren, Shenzhen (CN)

(73) Assignee: SHENZHEN CHINA STAR OPTOELECTRONICS TECHNOLOGY CO., LTD., Shenzhen, Guangdong (CN)

(21) Appl. No.: 13/522,326

(22) PCT Filed: Jun. 18, 2012
(86) PCT No.: PCT/CN12/77084

§ 371 Date: Jul. 15, 2012

(30) Foreign Application Priority Data
Jun. 13, 2012 (CN) 201210194839.4

(51) Int. Cl. H01L 33/44; H01L 33/08

(52) U.S. Cl. 257/88; 257/98; 257/E33.072; 257/E33.061

(57) ABSTRACT

The present invention provide a surface light source, wherein, the surface light source comprises a LED light source, the diffusion plate and condenser plant. The diffusion plate has a phosphor, and the diffusion plate and the LED light source are disposed separately to form a heat dissipation space. The condenser device disposes between the LED light source and the diffuser plate for converging the light emitted from LED light source to the diffusion plate.

Therefore, in the present invention, the phosphor is far away from the LED light source to avoid the heat generated by the LED chip directly transmitting to the phosphor such that the heat received by the phosphor is reduced, decreasing the temperature of the phosphor, and avoiding that the lighting efficiency of the phosphor become lower due to high temperature, and improve the color shill problem of the LED light source with manufacturing processes so as to increase the optical efficiency and optical quality of the surface light source and the display device using the same.

### BACKGROUND OF THE INVENTION

1. Field of the Invention

The present invention relates to display technology, and more particularly to a surface light source and a display device.

2. Description of Related Art

Currently, the surface light source of the display device usually uses a SMD (Surface Mounted Devices) type LED as a light source. Wherein, the SMD-type LED includes an LED chip and a plurality of phosphors, and the plurality of phosphors directly coat on the LED chip or uniformly distribute in the packaging materials of the LED itself

The luminance of a phosphor is reduced with increasing temperature; the current disposition of the phosphor is close to the LED chip such that the heat generated by the LED chip will affect the luminance of the phosphor, reducing the lighting efficiency of the phosphor. On the other hand, the luminance of the phosphor affect the light color of the LED and increase color shift of the LED so as to decrease the optical efficiency and optical quality of the surface light source.

### SUMMARY OF THE INVENTION

The main technical problems solved by the present invention are to provide a surface light source and a display device, to improve the lighting efficiency of a phosphor and reduce the color shift of the light source so as to improve the efficiency and optical quality of the surface light source and the display device.

To solve the above problems, a technical solution used in this invention is to provide a surface light source comprising:

an LED light source comprising an LED chip;

a diffusion plate disposed at light emitting direction of the LED light source, wherein the diffusion plate and the LED light source are disposed separately to form a heat dissipation space, and the diffusion plate comprises a light incident surface and a light emitting surface, and the light incident surface and the light emitting surface are disposed relatively, and a phosphor is disposed on the light emitting surface of the diffusion plate; and

a condenser device disposed between the LED light source and the diffuser plate for converging the lights emitted from LED light source to the diffusion plate, wherein, the condenser device is a condenser lens or a prism sheet.

wherein, the LED chip is a blue LED chip, and the phosphor is a combination of a red phosphor and a green phosphor or a yellow phosphor.

wherein, the LED chip is a ultraviolet LED chip and the phosphor is a combination of a red phosphor, a green phosphors, and a blue phosphor.

wherein, the phosphor material comprises a aluminate-based phosphor, a silicate-based phosphor, or a nitrogen oxide phosphor.

wherein, the diameter of the phosphor ranges from 5 μm to 15 μm.

To solve the above problems, a technical solution used in this invention is to provide a surface light source comprising:

an LED light source comprising an LED chip;

a diffusion plate disposed at light emitting direction of the LED light source, wherein a phosphor is disposed to the diffusion plate, and the diffusion plate and the LED light source are disposed separately to form a heat dissipation space; and

a condenser device disposed between the LED light source and the diffuser plate for converging the light emitted from LED light source to the diffusion plate.

wherein, the diffusion plate comprises a light incident surface and a light emitting surface, and the light incident surface and the light emitting surface are disposed relatively, and the phosphor is disposed on the light emitting surface of the diffusion plate, the light incident surface of the diffusion plate, or between the light emitting surface and the light incident surface of the diffusion plate.

wherein, the condenser device is a condenser lens or a prism sheet.

wherein, the LED chip is a blue LED chip, and the phosphor is a combination of a red phosphor and a green phosphor or a yellow phosphor.

wherein, the LED chip is a ultraviolet LED chip and the phosphor is a combination of a red phosphor, a green phosphors, and a blue phosphor.

wherein, the phosphor material comprises an aluminate-based phosphor, a silicate-based phosphor, or a nitrogen oxide phosphor.

wherein, the diameter of the phosphor ranges from 5 μm to 15 μm.

Another technical solution used to solve above technical problems is to provide a display device comprising a display panel and a surface light source for providing light source for the display panel, wherein, the surface light source comprises:

an LED light source comprising an LED chip;

a diffusion plate disposed at light emitting direction of the LED light source, wherein a phosphor is disposed to the diffusion plate, and the diffusion plate and the LED light source are disposed separately to form a heat dissipation space; and

a condenser device disposed between the LED light source and the diffuser plate for converging the light emitted from LED light source to the diffusion plate.

wherein, the diffusion plate comprises a light incident surface and a light emitting surface, and the light incident surface and the light emitting surface are disposed relatively, and the phosphor is disposed on the light emitting surface of the diffusion plate, the light incident surface of the diffusion plate, or between the light emitting surface and the light incident surface of the diffusion plate.

wherein, the condenser device is a condenser lens or a prism sheet.

wherein, the LED chip is a blue LED chip, and the phosphor is a combination of a red phosphor and a green phosphor or a yellow phosphor.

wherein, the LED chip is a ultraviolet LED chip and the phosphor is a combination of a red phosphor, a green phosphors, and a blue phosphor.

wherein, the phosphor material comprises an aluminate-based phosphor, a silicate-based phosphor, or a nitrogen oxide phosphor.

wherein, the diameter of the phosphor ranges from 5 μm to 15 μm.

The beneficial effects of the present invention are: comparing the prior art, the present invention provide a surface light source, wherein, the surface light source comprises a LED light source, the diffusion plate and condenser plant. The diffusion plate has a phosphor, and the diffusion plate and the LED light source are disposed separately to form a heat dissipation space. The condenser device disposes between the LED light source and the diffuser plate for converging the lights emitted from LED light source to the diffusion plate.

Therefore, in the present invention, the phosphor is far away from the LED light source to avoid the heat generated by the LED chip directly transmitting to the phosphor such that the heat received by the phosphor is reduced, decreasing the temperature of the phosphor, and avoiding that the lighting efficiency of the phosphor become lower due to high temperature, and improve the color shift problem of the LED light source so as to increase the optical efficiency and optical quality of the surface light source and the display device using the same.

### BRIEF DESCRIPTION OF THE DRAWINGS

FIG. 1 is a schematic drawing of the first embodiment of a surface light source of the present invention;

FIG. 2 is a schematic drawing of the second embodiment of a surface light source of the present invention;

FIG. 3 is a schematic drawing of the third embodiment of a surface light source of the present invention; and

FIG. 4 is a schematic drawing of a display device of the present invention.

### DETAILED DESCRIPTION OF THE PREFERRED EMBODIMENT

Please refer to FIG. 1, FIG. 1 is a schematic drawing of the first embodiment of a surface light source of the present invention. As shown in FIG. 1, the surface light source 100 of the present invention includes a diffusion plate 101, an LED light source 102, and a condenser device 103.

Wherein, the LED light source 102 includes an LED chip 104, and the diffusion plate 101 is disposed at light emitting direction of the LED light source 102, and a plurality of phosphors 130 are disposed on the light diffusion plate 101, and the diffusion plate 101 and the LED light source 102 are separated to form a heat dissipation space 105, as shown in FIG. 1. The condenser device 103 is disposed between the LED light source 102 and the diffusion plate 101 to converge the lights from the LED light source 102 to the diffusion plate 101.

In this embodiment, the diffusion plate 101 includes a light incident surface 110 and a light emitting surface 120. The light incident surface 110 and the light emitting surface 120 are disposed relatively, and the plurality of phosphors 130 are disposed on the light emitting surface 120. Specifically, the plurality of phosphors 130 are granular objects with the same diameters and are disposed uniformly on the light emitting surface 120 of the diffusion plate 101.

In this embodiment, each of the phosphors 130 comprises a red phosphor, a green phosphor, and a blue phosphor, or comprises a red phosphor and a green phosphor, or comprises a yellow phosphor. Correspondingly, each of the phosphors 130 comprises an aluminate-based phosphor, or a silicate-based phosphor, or a nitrogen oxide phosphor.

Wherein, the diameters of the plurality of phosphors 130 are selected preferably from 5 μm to 15 μm.

In this embodiment, the LED chip 104 is a blue light LED chip or an ultraviolet LED chip.

In this embodiment, the different light colors emitted from the different LED chips 104 could match the different phosphors to form white light emitted by the surface light source 100. For example, when the LED chips 104 is a blue LED chip, each of the phosphors 130 can be a combination of a red phosphor and a green phosphor, or only a yellow phosphor. When the LED chip 104 is an ultraviolet LED chip, each of the phosphors 130 can be a combination of a red phosphor, a green phosphor, and a blue phosphor.

In this embodiment, the condenser device 103 is a condenser lens, and is disposed between the LED light source 102 and the diffusion plate 101. The lights emitted from the LED light source 102 pass through the condenser device 103 for converging the lights to the diffusion plate 101. Therefore, reducing the scattering loss of the lights caused by passing through the heat dissipation space 105, and increasing the light incidence ratio of the diffusion plate 101, and increasing the lights recombined with the phosphors 130.

In other embodiments, the condenser device 103 can also be a prism sheet, or other devices with condenser function.

By matching the LED chips 104 and the plurality of phosphors 130, after the lights emitted from the LED light source 102 transmit to the plurality of phosphor 130, they can excite the plurality of phosphors 130 to produce a corresponding light. The lights produced by the plurality of phosphors 130 recombine with the lights emitted from the LED light source 102 to form the white lights.

Furthermore, the condenser device 103 converge the lights; therefore increase the lights for recombining with the plurality of phosphors 130. The LED light source 102 and the diffusion plate 101 are disposed separately to form the heat dissipation space 105 and to avoid the heat generated by the LED chip 104 directly transmitting to the plurality of phosphors 130 such that the lighting efficiency of each of the phosphors 130 is increasing.

It is worth noting that the backlight system of the present invention has other embodiments.

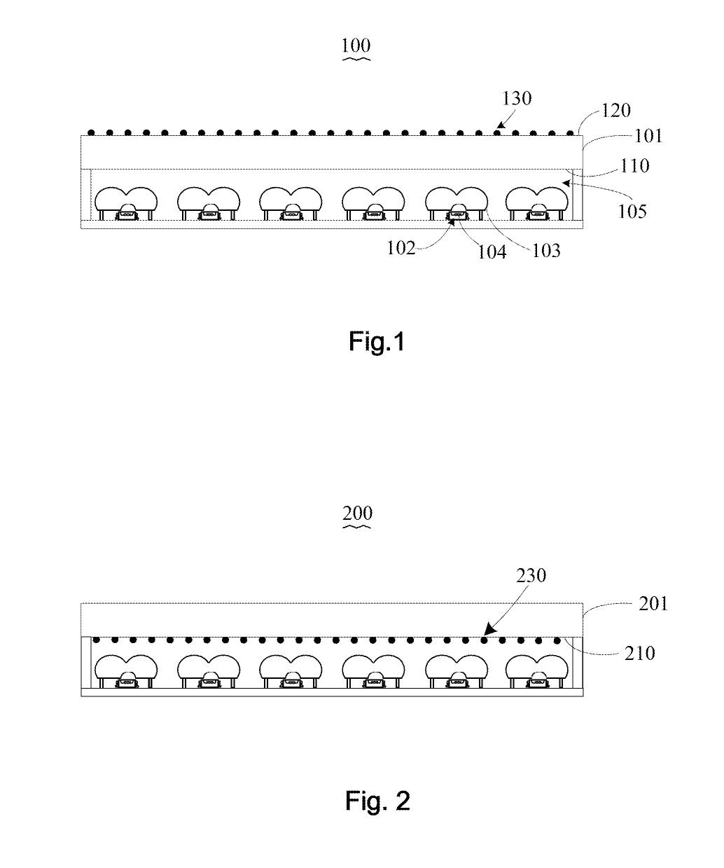

Please refer to FIG. 2, FIG. 2 is a schematic drawing of the second embodiment of a surface light source of the present invention. Comparing with the embodiment shown in FIG. 1, the main difference of the backlight system 200 is that the positions of the plurality of phosphor are different, wherein, a plurality of phosphors 230 are disposed at a light incident surface 210 of a diffusion plate 201.

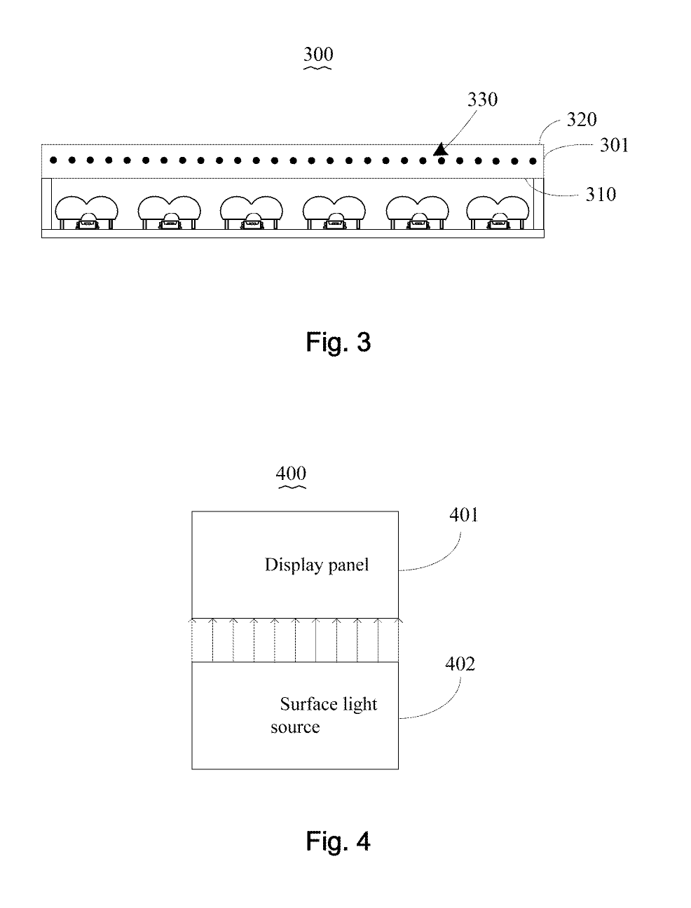

Please refer to FIG. 3, FIG. 3 is a schematic drawing of the third embodiment of a surface light source of the present invention. Comparing with the embodiment shown in the FIG. 1, the main difference of backlight system 300 is that the positions of the plurality of phosphors are different, wherein, a plurality of phosphors 330 are disposed between a light incident surface 310 and a light emitting surface 320 of a diffusion plate 301.

Please refer to FIG. 4, FIG. 4 is a schematic drawing of a display device of the present invention. As shown in FIG. 4, the display device of the present invention 400 comprises a display panel 401 and a surface light source 402, wherein, the surface light source 402 is to provide the lights for the display panel 401.

In this embodiment, the surface light source 402 is the surface light source 100, the surface light source 200, or the surface light source 300 shown in FIG. 1 to FIG. 3 respectively. The specific structures and operation principles could refer to the previous description.

In summary, in the present invention, phosphor is disposed on the diffusion plate, and the diffusion plate and the LED light source are disposed separately to form a heat dissipation space, and the condenser device could converge the lights emitted by the LED light source to the diffusion plate. Therefore, in the present invention the phosphor is far away from the LED light source to avoid the heat generated by the LED chip directly transmitting to the phosphor such that the heat received by the phosphor is reduced, decreasing the temperature of the phosphor, and avoiding that the lighting efficiency of the phosphor become lower due to high temperature, and improve the color shift problem the LED light source with LED manufacture process so as to increase the optical efficiency and optical quality of the surface light source and the display device using the same.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A surface light source comprising:
an LED light source comprising an LED chip;
a diffusion plate disposed at light emitting direction of the LED light source, wherein the diffusion plate and the LED light source are disposed separately to form a heat dissipation space, and the diffusion plate comprises a light incident surface and a light emitting surface, and the light incident surface and the light emitting surface are disposed relatively, and a phosphor is disposed on the light emitting surface of the diffusion plate; and
a condenser device disposed between the LED light source and the diffuser plate for converging the lights emitted from LED light source to the diffusion plate, wherein, the condenser device is a condenser lens or a prism sheet.

2. The surface light source according to claim 1, wherein, the LED chip is a blue LED chip and the phosphor is a combination of a red phosphor and a green phosphor, or a yellow phosphor.

3. The surface light source according to claim 1, wherein, the LED chip is an ultraviolet LED chip and the phosphor is a combination of a red phosphor, a green phosphor, and a blue phosphor.

4. The surface light source according to claim 1, wherein, the phosphor material comprises an aluminate-based phosphor, a silicate-based phosphor, or a nitrogen oxide phosphor.

5. The surface light source according to claim 1, wherein, the diameter of the phosphor ranges from 5 μm to 15 μm.

6. A surface light source comprising:
an LED light source comprising an LED chip;
a diffusion plate disposed at light emitting direction of the LED light source, wherein a phosphor is disposed to the diffusion plate, and the diffusion plate and the LED light source are disposed separately to form a heat dissipation space; and
a condenser device disposed between the LED light source and the diffuser plate for converging the light emitted from LED light source to the diffusion plate.

7. The surface light source according to claim 6, wherein, the diffusion plate comprises a light incident surface and a light emitting surface, and the light incident surface and the light emitting surface are disposed relatively, and the phosphor is disposed on the light emitting surface of the diffusion plate, the light incident surface of the diffusion plate, or between the light emitting surface and the light incident surface of the diffusion plate.

8. The surface light source according to claim 6, wherein, the condenser device is a condenser lens or a prism sheet.

9. The surface light source according to claim 6, wherein, the LED chip is a blue LED chip and the phosphor is a combination of a red phosphor and a green phosphor, or a yellow phosphor.

10. The surface light source according to claim 6, wherein, the LED chip is an ultraviolet LED chip and the phosphor is a combination of a red phosphor, a green phosphor, and a blue phosphor.

11. The surface light source according to claim 6, wherein, the phosphor material comprises an aluminate-based phosphor, a silicate-based phosphor. or a nitrogen oxide phosphor.

12. The surface light source according to claim 6, wherein, the diameter of the phosphor ranges from 5 μm to 15 μm.

13. A display device comprising a display panel and a surface light source for providing light source for the display panel. wherein, the surface light source comprises:
an LED light source comprising an LED chip;
a diffusion plate disposed at light emitting direction of the LED light source, wherein a phosphor is disposed to the diffusion plate, and the diffusion plate and the LED light source are disposed separately to form a heat dissipation space; and
a condenser device disposed between the LED light source and the diffuser plate for converging the light emitted from LED light source to the diffusion plate.

14. The surface light source according to claim 13, wherein, the diffusion plate comprises a light incident surface and a light emitting surface, and the light incident surface and the light emitting surface are disposed relatively, and the phosphor is disposed on the light emitting surface of the diffusion plate, the light incident surface of the diffusion plate, or between the light emitting surface and the light incident surface of the diffusion plate.

15. The surface light source according to claim 13, wherein, the condenser device is a condenser lens or a prism sheet.

16. The surface light source according to claim 13, wherein, the LED chip is a blue LED chip and the phosphor is a combination of a red phosphor and a green phosphor, or a yellow phosphor.

17. The surface light source according to claim 13, wherein, the LED chip is an ultraviolet LED chip and the phosphor is a combination of a red phosphor, a green phosphor, and a blue phosphor.

18. The surface light source according to claim 13, wherein, the phosphor material comprises an aluminate-based phosphor, a silicate-based phosphor, or a nitrogen oxide phosphor.

19. The surface light source according to claim 13, wherein, the diameter of the phosphor ranges from 5 μm to 15 μm.
